(19) United States
(12) Patent Application Publication
(10) Pub. No.: US 2024/0199952 A1
(43) Pub. Date: Jun. 20, 2024

(54) CORE-SHELL QUANTUM DOT AND METHOD FOR MANUFACTURING CORE-SHELL QUANTUM DOT

(71) Applicant: SHIN-ETSU CHEMICAL CO., LTD., Tokyo (JP)

(72) Inventors: Shinji AOKI, Annaka-shi (JP); Kazuya TOBISHIMA, Annaka-shi (JP); Yoshihiro NOJIMA, Annaka-shi (JP)

(73) Assignee: SHIN-ETSU CHEMICAL CO., LTD., Tokyo (JP)

(21) Appl. No.: 18/287,490

(22) PCT Filed: Mar. 24, 2022
(86) PCT No.: PCT/JP2022/014064

§ 371 Date: Oct. 19, 2023

(30) Foreign Application Priority Data
Apr. 28, 2021 (JP) 2021-075918

(51) Int. Cl. C09K 11/88; B82Y 15/00; B82Y 20/00; B82Y 30/00; B82Y 40/00; C09K 11/55; H01L 33/00; H01L 33/50; H10K 50/115

(52) U.S. Cl. CPC C09K 11/883; C09K 11/55; H01L 33/005; H01L 33/502; H10K 50/115; B82Y 15/00; B82Y 20/00; B82Y 30/00; B82Y 40/00

(57) ABSTRACT

A core-shell quantum dot and a method for manufacturing the core-shell quantum dots, wherein the core-shell quantum dot includes a semiconductor nanocrystal core including group II-VI elements having Zn and at least one of S, Se, or Te, and a semiconductor nanocrystal shell that coats the semiconductor nanocrystal core and contains a shell layer of a single layer or plurality of layers including group II-VI elements. At least one shell layer is an Mg-containing shell layer. As a result, a core-shell quantum dot is provided that exhibits an improved quantum yield and an improved fluorescence light emission efficiency and that has a narrow emission half-value width.

### TECHNICAL FIELD

The present invention relates to a core-shell quantum dot and a method for manufacturing a core-shell quantum dot.

### BACKGROUND ART

In a semiconductor nanoparticle single crystal, when crystal size becomes smaller than the Bohr radius of excitons, a strong quantum confinement effect occurs, and energy levels become discrete. The energy level depends on the crystal size, and a light absorption wavelength and a light emission wavelength can be calibrated with the crystal size. Additionally, light emission due to exciton recombination of semiconductor nanoparticle single crystals become highly efficient because of a quantum confinement effect, and the light emission is basically an emission line. It is attracting attention because it enables high-intensity narrow-band light emission if a particle size distribution with uniform size can be achieved. The phenomenon caused by the strong quantum confinement effect in such nanoparticles is called a quantum size effect, and studies are being conducted to widely apply and develop semiconductor nanocrystals utilizing this property as quantum dots.

As an application of quantum dots, its use as a fluorescent material for displays has been studied. If it is possible to achieve highly efficient light emission in a narrow band, it becomes possible to depict colors that could not be reproduced by existing technology, so it is attracting attention as a next-generation display material.

### CITATION LIST

### Non Patent Literature

Non Patent Document 1: Nozik et al. “Highly efficient band-edge emission from InP quantum dots.” Appl. Phys. Lett. 68. 3150 (1996)
Non Patent Document 2: J. P. Park, J.-J. Lee, S.-W. Kim, “Highly luminescent InP/GaP/ZnS QDs emitting in the entire color range via a heating up process”, Sci. Rep. 6: 30094 (2016)
Non Patent Document 3: Yang Li, Xiaoqi Hou, Xingliang Dai, Zhenlei Yao, Liulin Lv, Yizheng Jin, and Xiaogang Peng, “Stoichiometry-controlled InP-based quantum dots: synthesis, photoluminescence, and electroluminescence”, J. Am. Chem. Soc. 2019, 141, 6448-6452

### SUMMARY OF INVENTION

### Technical Problem

Although CdSe has been studied as a quantum dot having the best light emission characteristics, its high toxicity limits its use, and it has been necessary to study a Cd-free material. Accordingly, a material that attracted attention is a quantum dot with InP as a core. In 1996, three years after CdSe was reported by an MIT group, visible light emission has been confirmed (Non Patent Document 1), and then due to a quantum size effect, it has been clarified that it can cover RGB (red: λ=630 nm, 1.97 eV, green: λ=532 nm, blue: λ=465 nm), and has been energetically studied.

However, it is known that InP is inferior in optical characteristics to CdSe. One of the problems is the improvement of a quantum yield of the InP quantum dot. Because the surface of the quantum dot, which is basically a nano-sized semiconductor crystal particle, is highly active, and cores with a small bandgap are extremely reactive. When cores such as CdSe and InP alone are used, defects such as a dangling bond are likely to generate on a crystal surface. Consequently, a core-shell type semiconductor crystal particle has been manufactured using a semiconductor nanocrystal with a larger bandgap than the core and a smaller lattice mismatch than the core as the shell. For example, the CdSe-based quantum dot achieves a quantum yield of close to 100%. In contrast, the quantum yield of the InP-based quantum dot, which is also covered by the shell, can be improved, but the quantum yield is only 60% to 80%, and further improvement of the quantum yield is desired. In addition, the CdSe-based quantum dot has a light emission with full width at half maximum (FWHM) of less than 30 nm, which enables them to achieve sharp light emission characteristics required for display applications. On the other hand, the FWHM of the InP-based quantum dots is larger than 35 nm, and improvement of the FWHM is desired along with improvement of quantum efficiency.

One of the reasons for the larger FWHM is that InP has a larger bandgap variation concerning grain size compared with CdSe, resulting in a wider FWHM even if the grain size distribution is like that of CdSe. Because InP, which has a smaller effective mass, has a larger bandgap variation in relation to grain size than CdSe.

Consequently, a material, which has a large effective mass and the ability to display green and red color light emission due to the quantum size effect, is desired. One promising candidate for a quantum dot is a semiconductor nanoparticle with a composition of a mixed crystal of ZnTe mixed with ZnSe or ZnS. Although ZnS, ZnSe, and ZnTe have large effective masses and can be made with a smaller half-value width, unable to produce green or red light emissions on their own. However, a mixed crystal of ZnTe, and ZnSe or ZnS can have large bandgap bowings and produce green and red light emission, thus this makes the mixed crystal a promising candidate for a light emission material with a narrow half-value width. In fact, Non Patent Document 2 discloses that a light emission wavelength of 535 nm and a half-value width of 26 nm have been achieved and good light emission characteristics are expected, but the low quantum yield is mentioned as a problem to be solved.

On the other hand, in Non Patent Document 3, a shell layer of ZnSe or Zn mixed with ZnSeTe is grown and a high quantum yield of more than 80% is achieved, but the half-value width is as large as 45 nm at 519 nm. When the shell layer is grown, the light emission wavelength is shifting to the long wavelength, and confinement of the exciton in the core-shell structure is insufficient. Consequently, an ooze of the exciton to a large part of the shell section and half-value width is affected profoundly by not only a particle size distribution of the core but also a growth distribution of the shell.

As described above, quantum dots including group II-VI elements, such as the mixed crystal of ZnTe with ZnSe or ZnS as the core, have the problem of low quantum yield. A forming method of a shell such as ZnSe or ZnS, which is a well-known improving method for the quantum yield up to 80%, has been studied, but the problem of the long wavelength shift of the light emission wavelength and the wide half-value width of the light emission as wide as 35 nm require further improvement.

The present invention has been made given the above-described problems. An object of the present invention is to provide a core-shell quantum dot having improved quantum yield, fluorescent light emission efficiency, and light emission with a narrow half-value width, and a method for manufacturing the core-shell quantum dot.

### Solution to Problem

The present invention has been made to achieve objectives above-mentioned and provides a core-shell quantum dot comprising:
a semiconductor nanocrystal core including Zn and at least one of S, Se, or Te, and having group II-VI elements;
a semiconductor nanocrystal shell including a single or a plurality of shell layers having group II-VI elements coating the semiconductor nanocrystal core;
wherein at least one shell layer is a Mg-containing shell layer.

Such a core-shell quantum dot can effectively contain an ooze of the exciton, improving quantum yield and fluorescent light emission efficiency effectively without relying on shell thickness, resulting in a quantum dot with a narrow half-value width of light emission.

At this time, the core-shell quantum dot can have the semiconductor nanocrystal core which is a semiconductor nanocrystal selected from ZnTeₓSe₁₋ₓ or ZnTe_{y}S_{1-y}, or a mixed crystal thereof.

As a result, the quantum dot has an increased effective mass and a narrow half-value width of light emission.

At this time, the core-shell quantum dot can have the Mg-containing shell layer which is the semiconductor nanocrystal selected from Zn_{α}Mg_{1-α}Se or Zn_{β}Mg_{1-β}S, or a mixed crystal thereof.

Thus, a confinement effect to exciton is more improved.

In this case, a wavelength conversion member can be the wavelength conversion member including the core-shell quantum dot.

Consequently, the member becomes a high-quality wavelength conversion member.

The present invention is to reach an objective above-mentioned and provide a method for manufacturing core-shell quantum dots comprising:
a step of synthesizing a semiconductor nanocrystal core including Zn and at least one of S, Se or Te, and having group II-VI elements in a solution, and
a step of forming a shell layer containing Mg on a surface of the semiconductor nanocrystal core by adding a solution in which a cluster compound containing Zn and Mg is dissolved and a solution in which a group VI element precursor is dissolved to the solution in which the semiconductor nanocrystal core is synthesized.

This method for manufacturing the core-shell quantum dot enables stable and high Mg-doping and improves the quantum yield, and the fluorescent light emission efficiency, and produces the narrow half-value width of a light emission core-shell quantum dot.

### Advantageous Effects of Invention

As described above, the inventive core-shell quantum dot can effectively suppress the ooze of the exciton by forming at least one shell layer containing Mg on the semiconductor nanocrystal core composed of group II-VI elements including Zn and at least one of S, Se, or Te, and improves quantum yield and fluorescent light emission efficiency independent of the shell thickness. As a result, the quantum dot has a narrow half-value width of light emission. Consequently, the method for manufacturing core-shell quantum dots makes it possible to produce quantum dots as described above.

### BRIEF DESCRIPTION OF DRAWINGS

FIG. 1 is an example of a core-shell quantum dot of the present invention.

FIG. 2 is an example of a method for manufacturing the core-shell quantum dot.

### DESCRIPTION OF EMBODIMENTS

Hereinafter, embodiments of the present invention will be described in detail. However, the present invention is not limited thereto.

As described above, a core-shell quantum dot with an improved quantum yield and fluorescent light emission efficiency, a narrow half-value width of light emission, and a method for manufacturing the core-shell quantum dot is required. The present inventors have earnestly studied to solve the above problems and consequently found a semiconductor nanocrystal core including the group II-VI elements that contain Zn (zinc) and at least one of S (sulfur), Se (selenium), or Te (tellurium), and a semiconductor nanocrystal shell coating the semiconductor nanocrystal core and including one or more shell layers of the group II-VI elements, in which at least one of the shell layers is a shell layer containing Mg. Consequently, such core-shell quantum dot enables improvement of quantum yield and the fluorescent light emission efficiency, thus the quantum dot with a narrow half-value width of light emission. This finding has led to the completion of the present invention.

Additionally, the present inventors have found out that a method for manufacturing the core-shell quantum dot comprising a step of synthesizing a semiconductor nanocrystal core including Zn and at least one of S, Se, or Te, and having the group II-VI elements in a solution, a step of forming a shell layer containing Mg on a surface of the semiconductor nanocrystal core by adding a solution in which a cluster compound containing Zn and Mg is dissolved and a solution in which a group VI element precursor is dissolved to the solution in which the semiconductor nanocrystal core is synthesized, and thereby the quantum yield and the fluorescent light emission efficiency is improved having the narrow half-value width of light emission. This finding has led to the completion of the present invention.

Hereinafter, a description will be given regarding the attached drawings.

### [Core-Shell Quantum Dot]

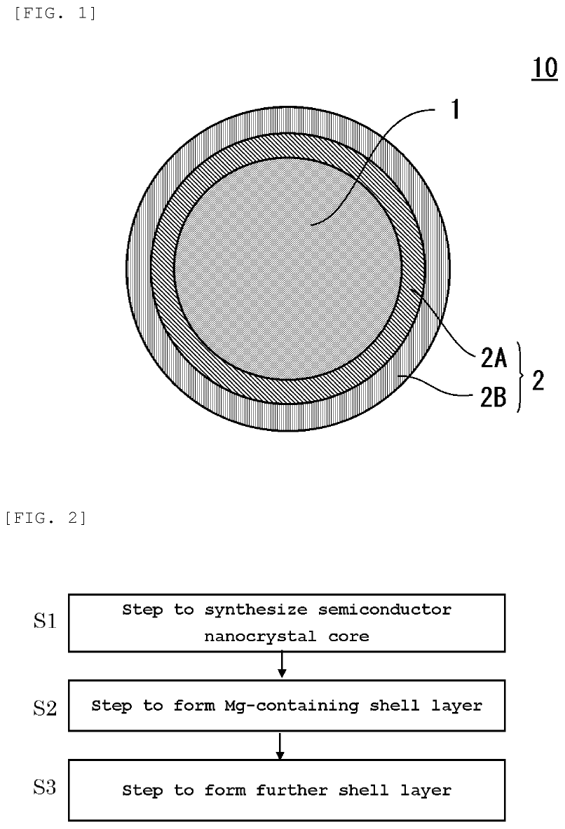

FIG. 1 shows an example of the core-shell dot of the present invention. As illustrated in FIG. 1, a core-shell quantum dot 10 of the present invention has a semiconductor nanocrystal core 1 and a semiconductor nanocrystal shell 2 coating the semiconductor nanocrystal core 1. The semiconductor nanocrystal core 1 has the group II-VI elements including Zn and at least one of S, Se, or Te. The semiconductor nanocrystal shell layer 2 has a single or a plurality of shell layers having the group II-VI elements and at least one shell layer is a shell layer 2A, which contains Mg. (hereafter may be referred to as the Mg-containing layer 2A). In the example illustrated in FIG. 1, the semiconductor nanocrystal shell 2 has another shell layer 2B in addition to Mg-containing shell layer 2A.

### (Semiconductor Nanocrystal Core)

Then, the semiconductor nanocrystal core 1 is described. The semiconductor nanocrystal core 1 is not limited to the cores as far as that contains the group II-VI elements including Zn and at least one of S, Se, or Te. In particular, it is preferable to contain at least ZnTe and a semiconductor nanocrystal selected from ZnSe or ZnS, or a mixed crystal thereof, and it is much preferable to a semiconductor nanocrystal selected from ZnTeₓSe₁₋ₓ (0<x<1) or ZnTe_{y}S_{1-y} (0<y<1), or a mixed crystal thereof. Such composition has a large effective mass and narrower half-value width of the light emission. A doping Se or S creates a large bandgap bowing, so that light emission wavelength of ZnTe nanoparticles, which is capable of light emission from 430 nm to 500 nm, enables long-wavelength shift (up to 630 nm) of light emission wavelength. Further, the half-value width of the light emission is improved.

### (Semiconductor Nanocrystal Shell)

Then, the semiconductor nanocrystal shell is described. The semiconductor nanocrystal shell may include at least one shell layer as the Mg-containing shell layer including a single or a plurality of shell layers having the group II-VI elements.

The Mg-containing layer shell 2A is not limited if it includes group II-VI elements and contains Mg. In the case of the semiconductor nanocrystal 2 include a plurality of shell layers, the shell layer other than Mg-containing layer 2A, such as the shell layer 2B in FIG. 1 may include or may not include Mg. In addition, it is preferable to form a ZnSe shell layer containing Mg as the Mg-containing layer 2A and form a shell layer other than the ZnSe layer as an outer shell layer 2B of the Mg-containing layer 2A, because a formation of a ZnS shell or the ZnS shell containing Mg makes a lattice mismatch smaller. Furthermore, MgSe and MgS react readily with e.g., water and oxygen, thus it is preferable to coat a top surface with ZnS which is stable in the atmosphere.

Additionally, Mg-containing layer 2A is preferably the semiconductor nanocrystal selected from Zn_{α}Mg_{1-α}Se (0<α<1) or Zn_{β}Mg_{1-β}S (0<β<1), or a mixed crystal thereof. This improves an exciton confinement effect more. To improve the exciton confinement by the core shell structure, adjusting the positional relation of a band offset between the core and the shell is required. When such as ZnTe, ZnTeₓSe₁₋ₓ or ZnTe_{y}S_{1-y} is used as the core, electron confinement is particularly challenging because a position of LUMO is greatly elevated compared to ZnSe or ZnS due to an effect from Te. Similarly, when a ZnS shell is attached to a ZnSe core, it is difficult to improve the quantum yield because confinement is difficult with ZnSeS due to the increased band gap caused by the quantum confinement effect of ZnSe, and it is difficult to form a neat shell layer with ZnS because of the large lattice mismatch. Consequently, it is considered that selecting a material, which can elevate the position of the shell-material LUMO, allows the improvement of the exciton confinement.

It is considered that the most optimum material for a higher LUMO position is MgSe or MgS. The band gaps are 3.59 eV (Zinc blend) for MgSe and 4.45 eV (Zinc blend) for MgS, which are larger than 2.82 eV for ZnSe and 3.78 eV for ZnS, respectively, and can be suitably used as the shell. Additionally, a lattice constant value is closer to ZnSe and ZnS respectively, so a forming of a mixed crystal is possible. However, when a core material is Zn-based group II-VI semiconductor nanoparticles such as ZnTeSe or ZnTeS, the crystal structure is of the sphalerite type. Thus, a sodium chloride type structure is a stable structure for MgSe and MgS, it is preferable to use Zn_{α}Mg_{1-α}Se or Zn_{β}Mg_{1-β}S, or a mixed crystal thereof, as a ZnSe or a ZnS mixed crystal for stable growth. This is derived from the mixed crystal including ZnSe or ZnS is the sphalerite type. In Zn_{α}Mg_{1-α}Se and Zn_{β}Mg_{1-β}S shells, Mg is preferably added at least 10%. Such an amount of Mg can stably establish a potential barrier needed for exciton confinement.

Moreover, a multi-staging of the shell structure further improves the quantum yield, thus a ZnMgSe shell layer may be formed followed by a mixed crystal shell layer with ZnMgSe and ZnMgS.

Furthermore, the forming of the mixed crystal shell layer including ZnSe and ZnS may be followed by the forming of the ZnS layer.

In addition, the forming of the shell layer above-mentioned can be confirmed by measuring particle image obtained by Transmission Electron Microscope (TEM), measuring an increase in particle size, performing elemental analysis using Energy Dispersive X-ray spectrometry (EDX), and calculating the percentage of Zn, Mg elements after synthesis of the Mg-containing shell layer.

Further, in the core-shell quantum dot of the present invention, an organic ligand called a ligand is preferably coordinated on the surface to impart dispersibility and reduce surface defects. The ligand preferably contains an aliphatic hydrocarbon from the viewpoint of improving dispersibility in a non-polar solvent. Examples of such ligands are oleic acid, stearic acid, palmitic acid, myristic acid, lauric acid, decanoic acid, octanoic acid, oleylamine, stearyl (octadecyl) amine, dodecyl (lauryl) amine, decylamine, octylamine, octadecane thiol, hexadecane thiol, tetradecane thiol, dodecane thiol, decane thiol, octane thiol, trioctylphosphine, trioctylphosphine oxide, triphenylphosphine, triphenylphosphine oxide, tributylphosphine, tributylphosphine oxide, and such ligand may be used alone or in combination of two or more.

### [Wavelength Conversion Member]

A wavelength conversion member of the present invention includes the core-shell quantum dot of the present invention. Hence a high-quality wavelength conversion member is provided. The wavelength conversion member is, for example, a resin composition in which the core-shell quantum dots of the present invention are dispersed in the resin. The specific configuration of the wavelength conversion members is not particularly limited thereto, but examples include wavelength conversion films and color filters in which the core-shell quantum dots are dispersed in the resin. The resin material, in this case, is not particularly limited thereto, but an agglomeration of the core-shell quantum dot or degradation of the fluorescent light emission efficiency is preferable. Thus, silicone resin, acrylic resin, epoxy resin, urethane resin, and fluorine resin are examples. These materials may have high transmittance to increase the fluorescent light emission efficiency as the wavelength conversion material and transmittance of 70% or more is especially preferred.

The wavelength conversion member, such as a backlight unit with the wavelength conversion film, and an image display device having the backlight unit on a light guiding panel surface in which a blue LED is installed, can be provided. It is also possible to provide an image display device in which the wavelength conversion member is placed between a light guiding panel surface to which the blue LED is installed and the liquid crystal display panel. The wavelength conversion member, including such as the backlight unit and the image display device, absorbs at least part of a blue light, which is a primary light and a light source, and emits a second light, which has a longer wavelength, thereby converting the primary light to light with a predetermined wavelength distribution that depends on the light emission wavelength of the quantum dot.

### [A Method for Manufacturing a Core-Shell Quantum Dot]

Then, a method for manufacturing the core-shell quantum dot of the present invention is described. The method for manufacturing a core-shell quantum dot of the present invention, as shown in FIG. 2, includes a step of synthesizing a semiconductor nanocrystal core including Zn and at least one of S, Se, or Te, and having group II-VI elements in a solution (core synthesizing step: S1), and a step of forming a shell layer containing Mg on a surface of the semiconductor nanocrystal core by adding a solution in which a cluster compound containing Zn and Mg is dissolved and a solution in which a group VI element precursor is dissolved to the solution in which the semiconductor nanocrystal core is synthesized (Mg-containing shell layer forming step: S2).

### (Core Synthesizing Step)

To begin with, a step of synthesizing a semiconductor nanocrystal core including Zn and at least one of S, Se, or Te, and having group II-VI elements shown in S1 of FIG. 1 is described. In S1, a semiconductor nanocrystal core composed of group II-VI elements can be synthesized by adding a group VI element precursor solution that includes at least one of S, Se, or Te to a group II element precursor solution containing Zn at a high temperature condition of 150° C. or more to 350° C. or less. The semiconductor nanocrystal core composed of group II-VI elements can be synthesized by adding a group II element precursor solution containing Zn and a group VI element precursor solution containing at least one of S, Se, or Te to a solution containing a higher-boiling organic solvent and a ligand such as an organic acid, amine, and phosphine, which are added to suppress an agglomeration, at a high temperature between 150° C. or more and 350° C. or less.

The group II element precursors include such as zinc fluoride, zinc chloride, zinc bromide, zinc iodide, zinc acetate, Zinc acetylacetonate, zinc oxide, zinc carbonate, zinc carboxylate, dimethyl zinc, diethyl zinc, zinc nitrate, zinc sulfate. By selecting raw materials from among these materials according to the reactivity of the group VI element precursor to being reacted, a mixed crystal containing good Zn and at least one of S, Se, or Te can be produced. For example, when reacting with such as a S=TOP (trioctylphosphine) solution, a Se=TOP solution, a Te-TOP solution, group II-VI element semiconductor nanocrystal cores uniformly doped with group VI element can be synthesized by using highly reactive diethylzinc as the group II element precursor. In addition, when group VI element precursors such as the S=TOP solution are treated with a lithium borohydride (e.g., “Super-Hydride” (registered trademark)) to improve nucleophilicity, or group VI element precursors with Te, Se, or S dissolved in diphenylphosphine instead of TOP as a reactivity adjustment, the semiconductor nanocrystal core composed of group II-VI elements uniformly doped with group VI elements can be synthesized by using zinc precursors made by reacting zinc oxide, zinc acetate, or zinc carbonate with organic acids as ligands.

Furthermore, a method to solve the group II element precursor in a solvent is not particularly limited thereto, for example, the method to dissolve in the solvent by heating a temperature of 100 to 180° C. is desired. Depressurization at this moment is particularly preferable because it removes dissolved oxygen and water from the dissolved solution.

The group VI element precursor can be selected appropriately from the viewpoint of controlling reactivity to produce the desired particle size and the particle size distribution. The group VI element precursor can be selected from, for example, the group VI precursors in which one or more of Se, S, or Te is dissolved in a solution, and the solution include aliphatic unsaturated hydrocarbon such as 1-octadecene, 1-hexadecene, and 1-dodecene, aliphatic saturated hydrocarbons such as n-octadecane, n-hexadecane, n-dodecane, phosphines such as trioctylphosphine, diphenylphosphine, and amines with long-chain alkyl groups such as oleylamine, dodecylamine, hexadecylamin. The group VI precursors can be also selected from alkyl thiol, trialkylphosphine sulfide, bistrialkylsilyl sulfide, trialkylphosphine selenide, trialkenylphosphine selenide, bistrialkylsilyl selenide, trialkylphosphine telluride, trialkenylphosphine telluride, and bistrialkylsilyl tellurium, etc.

In addition, a method to dissolve a solid group VI element precursor into a solvent is not limited thereto, for example, the method to dissolve the element by heating at a temperature of 100° C. to 250° C. is desirable.

The solvent is not particularly limited and may be selectable based on a synthesizing temperature and solubility of a precursor, for example, aliphatic unsaturated hydrocarbons such as 1-octadecene, 1-hexadecene, and 1-dodecene; aliphatic saturated hydrocarbons such as n-octadecane, n-hexadecane, n-dodecane; alkylphosphine such as trioctylphosphine; and amines with long-chain alkyl groups such as oleylamine, dodecylamine, hexadecylamine, can be used suitably.

A synthesizing temperature and a retention time are not limited thereto, either, as they are adjustable to obtain a desired particle size and a desired particle distribution.

### (Mg-Containing Shell Layer Forming Step)

Then, a step for forming a Mg-containing shell layer on the surface of the semiconductor nanocrystal core (Step 2) is described. The present inventors have studied various methods for a formation reaction of Mg-doped shell layer, but conventional methods had low doping efficiency because the amount of Mg-doped is low, only a few percent of doping has been achieved. Usually, a Mg precursor for doping is magnesium halide or magnesium long-chain carboxylate when zinc acetate or zinc long-chain carboxylate is used as a precursor. However, the Mg precursor shows a low reactivity and thus could be introduced into the shell layer just a little. On the other hand, when highly reactive alkylmagnesium reagent and zinc alkyl reagent is mixed, a reaction proceeds but hardly grows as a shell, but as separate particles.

Consequently, the present inventors find out a method to achieve a stable and high doping, such as 10% or more doping quantity to use a cluster compound containing Zn and Mg (a zinc-magnesium cluster compound in which Mg is solidly dissolved in Zn cluster compound). Zinc carbonylates acids such as zinc acetate and zinc stearate are heated under an inert atmosphere to 100° C. to 260° C. with degassing, and further heated to 240° C. to 360° C., where thermal decomposition occurs and forms cluster compounds such as a zinc four-nuclear complex and a zinc seven-nuclear complex. If Mg is doped during the formation of these cluster compounds, a cluster compound containing Zn and Mg i.e., a ZnMg precursor that is suitable for the formation of a ZnMgSe layer, can be produced.

Additionally, other Zn-cluster compounds such as polyoxomethalate (POM), organic-inorganic structure (MOF), and basic zinc carbonate are used suitably but are not limited to those compounds if Zn and Mg are mixed and integrated.

Zn precursors include such as zinc acetate, zinc acetylacetonate, and zinc carboxylate acid.

Mg precursors include such as magnesium carboxylates such as magnesium acetate and magnesium stearate, which may be selectable appropriately in accordance with the Zn precursor.

Regarding the group VI element precursor, similar to the method described in the core synthesizing step, may be selected appropriately in view of regulating reactivity to obtain a desired particle size and a particle distribution, such precursors include such as sulfur, alkylthiol, trialkylphosphine sulfide, bistrialkylsilyl sulfide, selenium, trialkylphosphine selenide, trialkenylphosphine selenide, and bistrialkylsilyl selenide. But these precursors are not particularly limited to thereto.

The method for dissolving a cluster compound containing Zn and Mg, which are the ZnMg precursor, is not particularly limited to, e.g., a method for dissolving by heating to a temperature of 100° C. to 180° C. is desirable. In particular, it is preferable to reduce the pressure at this time because dissolved oxygen and water can be removed from the dissolved solution. Moreover, the method for dissolving a solid group VI element precursor in the solvent is not particularly limited to, for example, the method for dissolving by heating to a temperature of 100° C. to 250° C. is desirable.

Furthermore, the method for dissolving the solid cluster compound including Zn and Mg (zinc-magnesium cluster compound) in the solvent is not particularly limited to, for example, the method for dissolving by heating to a temperature of 50° C. to 180° C. is desirable. In particular, it is preferable to reduce the pressure at this time because dissolved oxygen and water can be removed from the dissolved solution.

In addition, synthesis temperature and retention time are not limited as they are adjustable as needed to obtain the desired properties.

A method to confirm the formation of cluster compounds containing Zn and Mg can be exemplified by measurement using MALDI-TOFMS (matrix-assisted laser desorption/ionization time-of-flight mass spectrometer). The fragment peaks obtained from the MALDI-TOFMS measurement are consistent with the simulated fragment peaks, and the presence of Mg in the Zn cluster compounds can be confirmed. In the case of an unstable cluster compound, the shift of the peaks due to the confinement of Mg can also be confirmed by powder X-ray crystallography.

### (Shell Layer Forming Step)

As shown in S3 of FIG. 2, a shell layer 2B can be formed further. The shell layer 2B may contain Mg or maybe the shell layer without Mg. To simplify the production, it is preferable to grow the shell layer directly using the reaction solution after the step of forming the Mg-containing shell layer described above. A structure of the shell layer 2B is preferred to be a shell structure containing ZnSe, Zns, or a mixed crystal thereof, but not particularly limited thereto, however, considering stability, it is preferred to use ZnS on the outer surface. It is desirable to dissolve the group II element precursor and the group VI element precursor by adding each to the solution in which a ligand is dissolved to suppress aggregation after the shell layer synthesis. This reaction can synthesize the group II-VI element semiconductor nanocrystal shell by adding the group VI element precursor solution under high-temperature conditions between 150° C. and 350° C. after a mixed solution is made by adding the group II element precursor solution to the reaction solution used for the Mg-containing shell layer formation step.

The group II element precursors, as in the core synthesis step, include such as zinc fluoride, zinc chloride, zinc bromide, zinc iodide, zinc acetate, zinc acetylacetonate, zinc oxide, zinc carbonate, zinc carboxylate, dimethyl zinc, diethyl zinc, zinc nitrate, zinc sulfate. Because high reactivity is not required for the shell layer formation, zinc carboxylate acid, zinc acetate, and zinc halide are suitable due to ease of handling and compatibility with the solvent. A method of dissolving the solid group II element precursor material in a solvent is not limited thereto, and heating to a temperature of 100° C. to 180° C. to dissolve, for example, is desirable. Reducing the pressure at this time is particularly desirable because it removes dissolved oxygen and water from the dissolved solution.

As for the group VI element precursor, for example, sulfur, alkylthiol, trialkylphosphine sulfide, bistrialkylsilyl sulfide, selenium, trialkylphosphine selenide, trialkenylphosphine selenide, and bistrialkylsilyl selenide are included. Among these precursors, a sulfur source is preferred to be alkyl thiol having long-chain alkyl groups, such as dodecane thiol, considering a dispersion stability of the obtainable core-shell particles. A method of dissolving the solid group VI element precursor material in a solvent is not limited, and heating to a temperature of 100° C. to 180° C. to dissolve, for example, is desirable.

### [A Method for Manufacturing Wavelength Conversion Member]

When a wavelength conversion member, for example, a wavelength conversion film is produced, the core-shell quantum dot of the present invention can be dispersed in resin by mixing with the resin. In this process, the core-shell quantum dots dispersed in a solvent can be added to the resin and mixed to disperse them in the resin. The core-shell quantum dots in powder form removing the solvent can also be dispersed in the resin by adding and kneading the core-shell quantum dots to the resin. Alternatively, there is a method in which monomers and oligomers of resin constituents are polymerized in the coexistence of the core-shell quantum dots. The method of dispersing the core-shell quantum dots in resin is not restricted and can be selected appropriately according to the purpose.

The solvent, in which the core-shell quantum dots are dispersed, is not restricted, as long as it is compatible with the resin to be used. Resin materials are not restricted, and such as silicone resin, acrylic resin, epoxy resin, and urethane resin can be selected according to the desired properties. These resins may have a high transmittance to increase efficiency as the wavelength conversion material, and the transmittance of 80% or more are particularly desirable.

Materials other than the core-shell quantum dot may be included, fine particles such as silica, zirconia, alumina, and titania may be included as light scatterers, as well as inorganic fluorescent materials and organic fluorescent materials. YAG, LSN, LYSN, CASN, SCASN, KSF, CSO, β-SIALON, GYAG, LuAG, and SBCA are inorganic fluorescent materials, while perylene derivatives and anthraquinone derivatives anthracene derivatives, phthalocyanine derivatives, cyanine derivatives, dioxazine derivatives, benzoxazinone derivatives, coumarin derivatives, quinophthalone derivatives, benzoxazole derivatives, pyralizone derivatives are exemplified as organic fluorescent materials.

The wavelength conversion materials can also be obtained by coating a resin composition, in which the core-shell quantum dot is dispersed in the resin, on a transparent film such as PET or polyimide, curing the resin to form the resin layer and laminating thereof. The coating on the transparent film can be applied by atomizing methods such as spray and inkjet, spin coating, bar coater, doctor blade methods, gravure printing methods, and offset printing methods. The thickness of the resin layer and transparent film is not particularly restricted and can be selected according to the application.

### EXAMPLE

Hereinafter, the present invention will be specifically described with reference to Examples. However, the present invention is not limited thereto.

### Example 1

### (Core Synthesis Step)

Firstly, a ZnSeTe core is synthesized as a semiconductor nanocrystal core. To begin with, 2 mL of oleic acid and 10 mL of 1-octadecene were poured into a flask, heated, and stirred at 100° C. under reduced pressure, and degassed for 1 hour. Nitrogen was then purged into the flask and heated to 290° C. When the temperature of a solution was stabilized, a Te=TOP solution was adjusted to 0.3 M by adding Te to trioctylphosphine separately and dissolving it, and a Se=TOP solution was adjusted to 0.3 M by adding Se to trioctylphosphine and dissolving it. Both solutions were added to a diethylzinc solution to achieve a desired composition ratio, then the solution adjusted as a Zn-group VI element precursor solution was added and maintained at a temperature of 270° C. for 30 minutes. The solution turned into reddish-brown color and a formation of core particles was confirmed.

### (Mg-Containing Shell Layer Forming Step)

ZnMgSe was then formed as an Mg-containing shell layer. In another flask, 2.53 g (4.0 mmol) of zinc stearate and 1.18 g (2.0 mmol) of magnesium stearate were added, heated to 150° C. and stirred. This solution was degassed for one hour while dissolving, and then heated to 320° C. and held for one hour before adding 6 ml of octadecene, whence zinc stearate magnesium cluster precursor octadecene solution was prepared. The 4.5 mL (2.8 mmol) of zinc stearate magnesium cluster precursor octadecene solution was added to the reaction solution heating at 270° C., in which the core had been synthesized, and then stirred for 30 minutes. Then, 0.4 g (5 mmol) of selenium and 4 mL of trioctylphosphine were added to another flask and heated to 150° C. to dissolve for preparing a solution of 1.25 M of a trioctylphosphine selenide. The 2.4 mL (3.0 mmol) of an adjusted trioctylphosphine selenide solution was added to the reaction solution and stirred for 30 minutes.

### (Shell Layer Forming Step)

And lastly, a ZnS shell layer was formed. In another flask, 3.0 g (4.74 mmol) of zinc stearate and 15 mL of octadecene were added, heated to 100° C. to dissolve, stirred for one hour, and degassed by vacuumization to adjust a zinc precursor solution. This 10 mL of a zinc precursor solution was added to the reaction solution at a temperature of 270° C. where the Mg-containing shell layer was formed and held for 30 minutes. Then, 0.16 g (5 mmol) of sulfur was dissolved by adding 4 mL of trioctylphosphine and heating to 150° C. The 1.25 M of trioctylphosphine sulfide solution was adjusted and 1.0 mL of the solution was added to the reaction solution and stirred for one hour. The 0.44 g (2.2 mmol) of zinc acetate was added to the reaction solution, heated to 100° C., and stirred to dissolve under reduced pressure. The flask was again purged with nitrogen and the temperature was raised to 230° C., then 0.98 mL (4 mmol) of 1-dodecanethiol was added to the reaction solution and held for 1 hour.

The solution gained was cooled to room temperature, in which ethanol was added, and a nanoparticle was precipitated to remove a supernatant solution by centrifugation. Further, hexane was added to the solution to disperse, and ethanol was added again, centrifuged, and the supernatant was removed and redispersed in hexane to adjust a ZnSeTe/ZnMgSe/ZnS hexane solution.

### Comparative Example 1

### (Core Synthesis Step)

A core synthesis solution adjusted under the same condition as in Example 1 was made, except for the Mg-containing shell layer formation step.

### (Shell Layer Forming Step)

ZnSeS and ZnS were formed sequentially as a core-coating shell layer. In another flask, 6.0 g (9.48 mmol) of zinc stearate and 30 mL of octadecene were added, heated to 100° C., and dissolved. This solution was stirred and degassed for one hour under a vacuum to adjust a zinc precursor solution. This 10 mL of zinc precursor solution was added to the reaction solution at a temperature of 270° C., in which a core has been synthesized, then held for 30 minutes. Then, 4 mL of trioctylphosphine were added to 0.11 g (3.5 mmol) of sulfur, 0.12 g (1.5 mmol) of selenium, and dissolved heating to 150° C. The 1.25 M of trioctylphosphine sulfide selenide solution was adjusted, 1.0 mL of the solution was added to the reaction solution, and stirred for one hour. Then 10 mL of an adjusted zinc precursor solution was added to the reaction solution again and stirred for 30 minutes. In another flask, 0.16 g (5 mmol) of sulfur and 4 mL of a trioctylphosphine were added and heated to a temperature of 150° C. to dissolve, 1.25 M of a trioctylphosphine sulfide solution was adjusted, and added 1.0 mL to the reaction solution, then stirred for one hour. The 0.44 g (2.2 mmol) of zinc acetate was added to the reaction solution, heated to 100° C., and stirred to dissolve under reduced pressure. The flask was again purged with nitrogen and the temperature was raised to 230° C., then 0.98 mL (4 mmol) of 1-dodecanethiol was added to the reaction solution and held for one hour.

The solution gained was cooled to room temperature, in which ethanol was added, and the nanoparticle was precipitated to remove a supernatant solution by centrifugation. Further, hexane was added to the solution to disperse, and ethanol was added again, centrifuged, and the supernatant was removed and redispersed in hexane to adjust a ZnSeTe/ZnSeS/ZnS hexane solution.

### Example 2

A reaction solution was made under the same conditions as in Example 1, adjusted up to an Mg-containing shell layer. In another flask, 6.0 g (9.48 mmol) of zinc stearate and 30 mL of octadecene were added, heated to 100° C., dissolved and stirred, and degassed under vacuum for one hour to adjust a zinc precursor solution. The 10 mL of zinc precursor solution was added to the reaction solution at a temperature of 270° C. where the Mg-containing shell layer was formed and held for 30 minutes. Then, 4 mL of trioctylphosphine were added to 0.11 g (3.5 mmol) of sulfur, 0.12 g (1.5 mmol) of selenium, and dissolved heating to 150° C. The 1.25 M of a trioctylphosphine sulfide selenide solution was adjusted and 1.0 mL of the solution was added to a reaction solution and stirred for one hour. Then 10 mL of an adjusted zinc precursor solution was added to the reaction solution again and stirred for 30 minutes. In another flask, 0.16 g (5 mmol) of sulfur and 4 mL of trioctylphosphine were added and heated to a temperature of 150° C. to dissolve, 1.25 M of a trioctylphosphine sulfide solution was adjusted, and 1.0 mL of the solution was added to the reaction solution, then stirred for one hour. The 0.44 g (2.2 mmol) of zinc acetate was added to the reaction solution, heated to 100° C., and stirred to dissolve under reduced pressure. The flask was again purged with nitrogen and the temperature was raised to 230° C., then 0.98 mL (4 mmol) of 1-dodecanethiol was added to the reaction solution and held for 1 hour.

The solution gained was cooled to room temperature, in which ethanol was added, and the nanoparticle was precipitated to remove a supernatant solution by centrifugation. Further, hexane was added to the solution to disperse, and ethanol was added again, centrifuged, and the supernatant was removed and redispersed in hexane to adjust a ZnSeTe/ZnMgSe/ZnSeS/ZnS hexane solution.

### [Average Particle Size Measurement]

To measure the average particle size of obtained core-shell quantum dots, at least 20 particles were directly observed using a Transmission Electron Microscope (TEM). The diameter of a circle having the same area as a projected area of the particles was calculated, and their average value was applied.

### (Elemental Analysis)

Samples were collected after a core synthesis, a Mg-containing shell layer formation, and a shell layer formation, respectively. The sample solutions for each process were prepared by adding ethanol to precipitate the particles and then adding hexane to redispersion. Elemental analysis was performed using Energy Dispersive X-ray spectrometry (EDX), and the elemental ratio was calculated for Zn, Mg, Te, Se, and S.

### [Light Emission Wavelength, Light Emission Half-Value Width, Light Emission Efficiency Measurement]

In Examples 1 and 2, and Comparative Example 1, fluorescent light emission evaluation of the quantum dot was measured by the light emission wavelength of the quantum dots, the half-value width of a fluorescent light emission, and fluorescent light emission efficiency (internal quantum efficiencies) at an excitation wavelength of 450 nm using the quantum efficiency measurement system (QE-2100) manufactured by Otsuka Electronics Co., Ltd.

The measurement results of Examples 1 and 2, and Comparative Example 1 are summarized in Table 1 below.

TABLE 1

| | | | | | Mg-containing | | | |
|---|---|---|---|---|---|---|---|---|
| | Core | | | | shell layer | | Shell layer | |
| Example 1 | Average | | 4.8 | nm | 6.8 | nm | 9.1 | nm |
| | particle size | | | | | | | |
| | Elemental | Zn | 52.1 | % | 31.2 | % | 35.6 | % |
| | analysis | Mg | 0 | % | 18.8 | % | 14.4 | % |
| | | Te | 28.4 | % | 1.5 | % | 1.1 | % |
| | | Se | 19.5 | % | 48.5 | % | 37.2 | % |
| | | S | 0 | % | — | % | 11.6 | % |
| | Light emission wavelength | | | | | | 539 | nm |
| | light emission half width | | | | | | 31 | nm |
| | Internal quantum efficiencies | | | | | | 41 | % |
| Comparative | Average | | 4.8 | nm | — | nm | 8.2 | nm |
| Example 1 | particle size | | | | | | | |
| | Elemental | Zn | 52.1 | % | — | % | 50 | % |
| | analysis | Mg | 0 | % | — | % | 0 | % |
| | | Te | 28.4 | % | — | % | 4.2 | % |
| | | Se | 19.5 | % | — | % | 7.7 | % |
| | | S | 0 | % | — | % | 38 | % |
| | Light emission wavelength | | | | | | 532 | nm |
| | light emission half width | | | | | | 38 | nm |
| | Internal quantum efficiencies | | | | | | 7 | % |
| Example 2 | Average | | 4.8 | nm | 6.8 | nm | 9.7 | nm |
| | particle size | | | | | | | |
| | Elemental | Zn | 52.1 | % | 31.2 | % | 36.6 | % |
| | analysis | Mg | 0 | % | 18.8 | % | 13.4 | % |
| | | Te | 28.4 | % | 1.5 | % | 1.1 | % |
| | | Se | 19.5 | % | 48.5 | % | 35.6 | % |
| | | S | 0 | % | — | % | 13.3 | % |

| | | |
|---|---|---|
| Light emission wavelength | 540 | nm |
| light emission half width | 29.4 | nm |
| Internal quantum efficiencies | 62 | % |

As shown in Table 1, the average particle size of Examples 1 and 2 was about 2 nm larger after the synthesis of the Mg-containing shell layer than after the synthesis of the core. Furthermore, an Mg element was detected by elemental analysis and a ZnMgSe is considered to have been formed. The shell layers in Examples 1 and 2 contain Mg because they were formed in the solution in which the Mg-containing shell layer was formed. Comparing a light emission characteristic after forming the shells, the light emission wavelengths of Examples 1 and 2 were shifted to a longer wavelength than that of Comparative Example 1, but a half-value width of the light emission is smaller than that of Comparative Example suggesting that the shell layer was likely to be formed in good shape due to the forming of a small shell with a lattice mismatch. Fluorescent light emission efficiency (internal quantum efficiencies) in Examples 1 and 2 was confirmed to be higher than that of Comparative Example 1, thus the Mg-containing shell layer was shown to be effective in improving a quantum yield. Additionally, the formation of the shell layer did not cause a long wavelength shift accompanied by a deterioration of the half-value width of light emission due to agglomeration, indicating that an adjustment of the light emission wavelength is easy. In addition, it was shown that the synthesis method for the core-shell quantum dot could be easily scaled up because core synthesis, Mg-containing shell layer forming, and shell layer forming could be successively performed.

As described above, according to the examples of the present invention, the core-shell quantum dots with the improved quantum yield and the fluorescent light emission efficiency, and the narrow half-value width of light emission could be obtained.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1-5. (canceled)

6. A core-shell quantum dot comprising:
a semiconductor nanocrystal core including Zn and at least one of S, Se, or Te, and having group II-VI elements;
a semiconductor nanocrystal shell including a single or a plurality of shell layers having group II-VI elements coating the semiconductor nanocrystal core;
wherein at least one shell layer is a Mg-containing shell layer.

7. The core-shell quantum dot according to claim 6, wherein the semiconductor nanocrystal core is the semiconductor nanocrystal selected from ZnTeₓSe₁₋ₓ or ZnTe_{y}S_{1-y}, or a mixed crystal thereof.

8. The core-shell quantum dot according to claim 6, wherein the Mg-containing shell layer is the semiconductor nanocrystal selected from Zn_{α}Mg_{1-α}Se or Zn_{β}Mg_{1-β}S, or a mixed crystal thereof.

9. The core-shell quantum dot according to claim 7, wherein the Mg-containing shell layer is the semiconductor nanocrystal selected from Zn_{α}Mg_{1-α}Se or Zn_{β}Mg_{1-β}S, or a mixed crystal thereof.

10. A wavelength conversion member containing the core-shell quantum dot according to claim 6.

11. A wavelength conversion member containing the core-shell quantum dot according to claim 7.

12. A wavelength conversion member containing the core-shell quantum dot according to claim 8.

13. A wavelength conversion member containing the core-shell quantum dot according to claim 9.

14. A method for manufacturing core-shell quantum dots comprising:
a step of synthesizing a semiconductor nanocrystal core including Zn and at least one of S, Se or Te, and having group II-VI elements in a solution, and
a step of forming a shell layer containing Mg on a surface of the semiconductor nanocrystal core by adding a solution in which a cluster compound containing Zn and Mg is dissolved and a solution in which a group VI element precursor is dissolved to the solution in which the semiconductor nanocrystal core is synthesized.
